(19) United States
(12) Patent Application Publication
(10) Pub. No.: US 2024/0194452 A1
(43) Pub. Date: Jun. 13, 2024

(54) BIAS SUPPLY WITH RESONANT SWITCHING

(71) Applicant: Advanced Energy Industries, Inc., Denver, CO (US)

(72) Inventor: Maneesh Kumar Singh, Fort Collins, CO (US)

(21) Appl. No.: 18/584,816

(22) Filed: Feb. 22, 2024

Related U.S. Application Data
(63) Continuation of application No. 17/584,940, filed on Jan. 26, 2022, now Pat. No. 11,942,309.

(51) Int. Cl. H01J 37/32; H01J 37/305; H01L 21/3065; H01L 21/67; H05H 1/24

(52) U.S. Cl. CPC H01J 37/32284; H01J 37/3053; H01L 21/3065; H01L 21/67069; H05H 1/24

(57) ABSTRACT

Bias supplies and plasma processing systems are disclosed. One bias supply comprises an output node, a return node, and a power section coupled to the output node and the return node. A resonant switch section is coupled to the power section at a first node, a second node, and a third node wherein the resonant switch section is configured to connect and disconnect a current pathway between the first node and the second node to apply an asymmetric periodic voltage waveform at the output node relative to the return node. The asymmetric periodic voltage waveform includes a first portion that begins with a first negative voltage and changes to a positive peak voltage, a second portion that changes from the positive peak voltage level to a third voltage level and a fourth portion that includes a negative voltage ramp from the third voltage level to a fourth voltage level.

### CLAIM OF PRIORITY UNDER 35 U.S.C. § 120

The present Application for Patent is a continuation of U.S. patent application Ser. No. 17/584,940 entitled “BIAS SUPPLY WITH RESONANT SWITCHING” filed Jan. 26, 2022 and assigned to the assignee hereof and hereby expressly incorporated by reference herein.

### BACKGROUND

### Field

The present invention relates generally to power supplies, and more specifically to power supplies for applying a voltage for plasma processing.

### Background

Many types of semiconductor devices are fabricated using plasma-based etching techniques. If it is a conductor that is etched, a negative voltage with respect to ground may be applied to the conductive substrate so as to create a substantially uniform negative voltage across the surface of the substrate conductor, which attracts positively charged ions toward the conductor, and as a consequence, the positive ions that impact the conductor have substantially the same energy.

If the substrate is a dielectric, however, a non-varying voltage is ineffective to place a voltage across the surface of the substrate. But an alternating current (AC) voltage (e.g., high frequency AC or radio frequency (RF)) may be applied to the conductive plate (or chuck) so that the AC field induces a voltage on the surface of the substrate. During the positive peak of the AC cycle, the substrate attracts electrons, which are light relative to the mass of the positive ions; thus, many electrons will be attracted to the surface of the substrate during the positive peak of the cycle. As a consequence, the surface of the substrate will be charged negatively, which causes ions to be attracted toward the negatively-charged surface during the rest of the AC cycle. And when the ions impact the surface of the substrate, the impact dislodges material from the surface of the substrate—effectuating the etching.

In many instances, it is desirable to have a narrow (or specifically tailorable) ion energy distribution, but applying a sinusoidal waveform to the substrate induces a broad distribution of ion energies, which limits the ability of the plasma process to carry out a desired etch profile. Known techniques to achieve a narrow ion energy distribution are expensive, inefficient, difficult to control, and/or may adversely affect the plasma density. As a consequence, many of these known techniques have not been commercially adopted. Accordingly, a system and method are needed to address the shortfalls of present technology and to provide other new and innovative features.

### SUMMARY

An aspect may be characterized as a bias supply to apply a periodic voltage comprising an output node, a return node, and a resonant switch section. The resonant switch section comprises a first node, a second node, a third node, and a first current pathway between the first node and the second node, which comprises a series combination of a switch and a diode. The resonant switch section also comprises a second current pathway between the second node and the third node that comprises a diode and an inductive element. A power section of the bias supply comprises a first voltage source coupled between the third node and the first node and a second voltage source coupled to the return node. When the switch is closed, unidirectional current in the first and second current pathways causes an application of the periodic voltage between the output node and the return node.

Another aspect may be characterized as a bias supply comprising an output node, a return node, and a power section coupled to the output node and the return node. The bias supply also comprises a resonant switch section coupled to the power section at a first node, a second node, and a third node wherein the resonant switch section is configured to connect and disconnect a current pathway between the first node and the second node to cause an application of an asymmetric periodic voltage waveform at the output node relative to the return node. Each cycle of the asymmetric periodic voltage waveform includes a first portion that begins with a first negative voltage and changes to a positive peak voltage, a second portion that changes from the positive peak voltage level to a third voltage level and a fourth portion that includes a negative voltage ramp from the third voltage level to a fourth voltage level.

### BRIEF DESCRIPTION OF THE DRAWINGS

FIG. 1 is a block diagram depicting an exemplary plasma processing environment in which bias supplies disclosed herein may be utilized;

FIG. 2 is a schematic diagram depicting an exemplary bias supply;

FIG. 3 is a schematic diagram electrically representing aspects of a plasma processing chamber;

FIGS. 4A, 4B, 4C, 4D, 4E, 4F, and 4G each depict an example of the bias supply depicted in FIG. 2;

FIGS. 5A, 5B, and 5C are schematic diagrams, and each of FIGS. 5A, 5B, and 5C depict an example of the resonant switch section;

FIG. 6A includes graphs depicting operational aspects of the bias supplies disclosed herein in an example mode of operation;

FIG. 6B includes graphs depicting operational aspects of the bias supplies disclosed herein in another example mode of operation; and

FIG. 7 is a block diagram depicting components that may be utilized to implement control aspects disclosed herein.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

Preliminary note: the flowcharts and block diagrams in the following Figures illustrate the architecture, functionality, and operation of possible implementations of systems, methods and computer program products according to various embodiments. In this regard, some blocks in these flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

For the purposes of this disclosure, source generators are those whose energy is primarily directed to generating and sustaining the plasma, while “bias supplies” are those whose energy is primarily directed to generating a surface potential for attracting ions and electrons from the plasma.

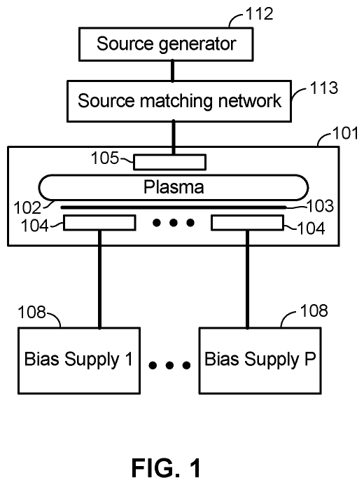

Described herein are several embodiments of novel bias supplies that may be used to apply a periodic voltage function to a substrate support in a plasma processing chamber. Referring first to FIG. 1, shown is an exemplary plasma processing environment (e.g., deposition or etch system) in which bias supplies may be utilized. The plasma processing environment may include many pieces of equipment coupled directly and indirectly to a plasma processing chamber 101, within which a volume containing a plasma 102 and workpiece 103 (e.g., a wafer) and electrodes 104 (which may be embedded in a substrate support) are contained. The equipment may include vacuum handling and gas delivery equipment (not shown), one or more bias supplies 108, one or more source generators 112, and one or more source matching networks 113. In many applications, power from a single source generator 112 is connected to one or multiple source electrodes 105. The source generator 112 may be a higher frequency RF generator (e.g., 13.56 MHz to 120 MHz). The electrode 105 generically represents what may be implemented with an inductively coupled plasma (ICP) source, a dual capacitively-coupled plasma source (CCP) having a secondary top electrode biased at another RF frequency, a helicon plasma source, a microwave plasma source, a magnetron, or some other independently operated source of plasma energy.

In variations of the system depicted in FIG. 1, the source generator 112 and source matching network 113 may be replaced by, or augmented with, a remote plasma source. And other variations of the system may include only a single bias supply 108.

While the following disclosure generally refers to plasma-based wafer processing, implementations can include any substrate processing within a plasma chamber. In some instances, objects other than a substrate can be processed using the systems, methods, and apparatus herein disclosed. In other words, this disclosure applies to plasma processing of any object within a sub-atmospheric plasma processing chamber to affect a surface change, subsurface change, deposition or removal by physical or chemical means.

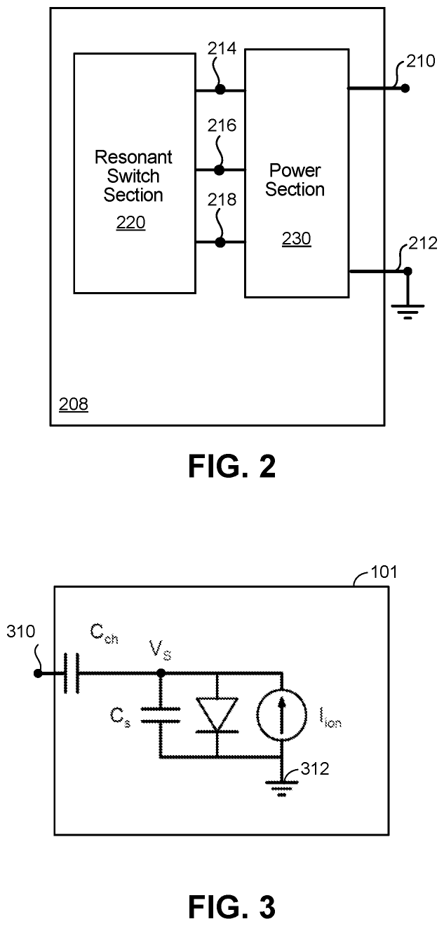

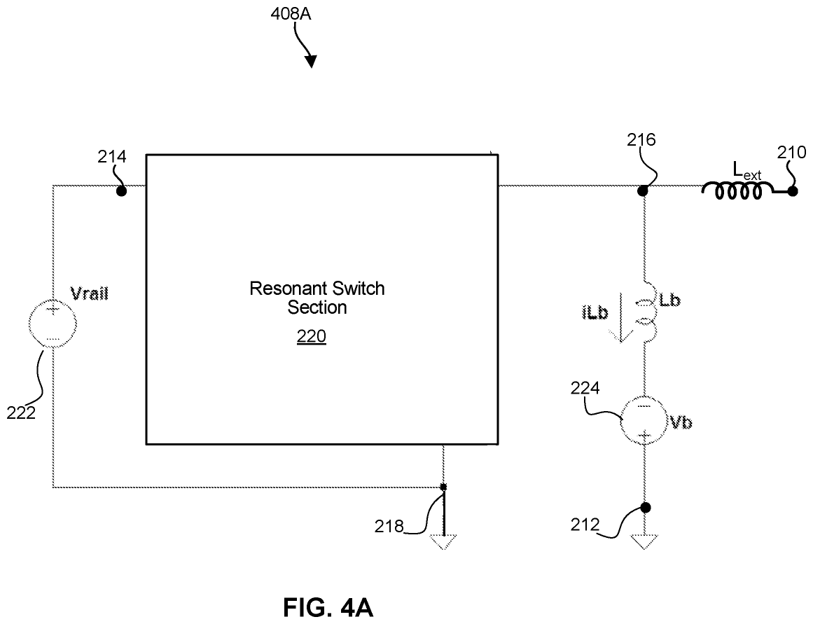

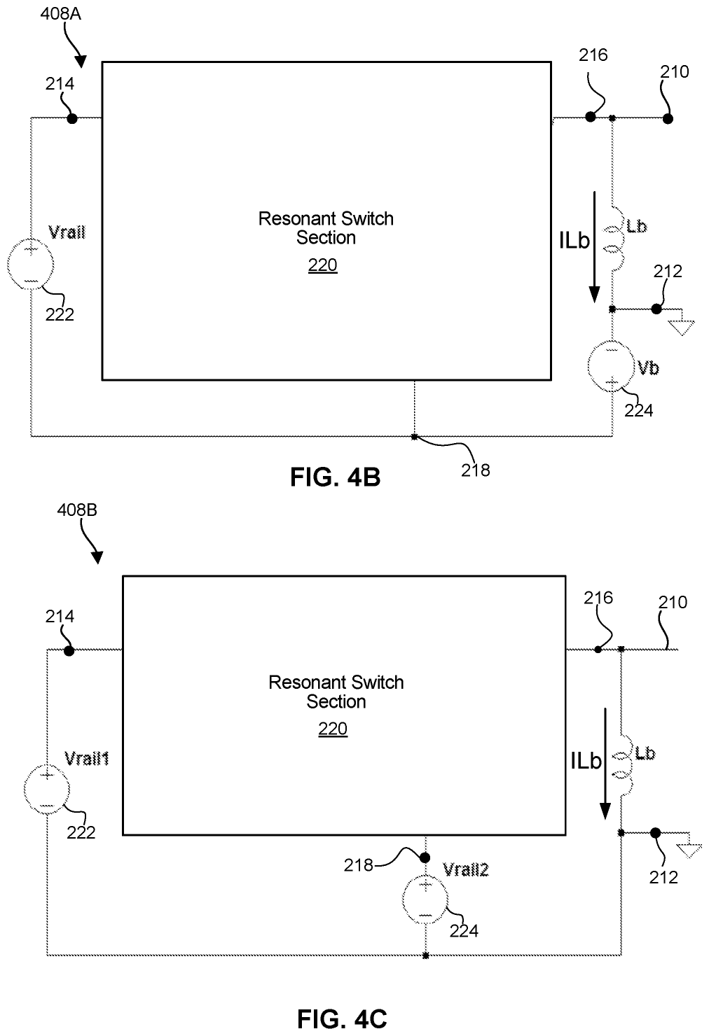

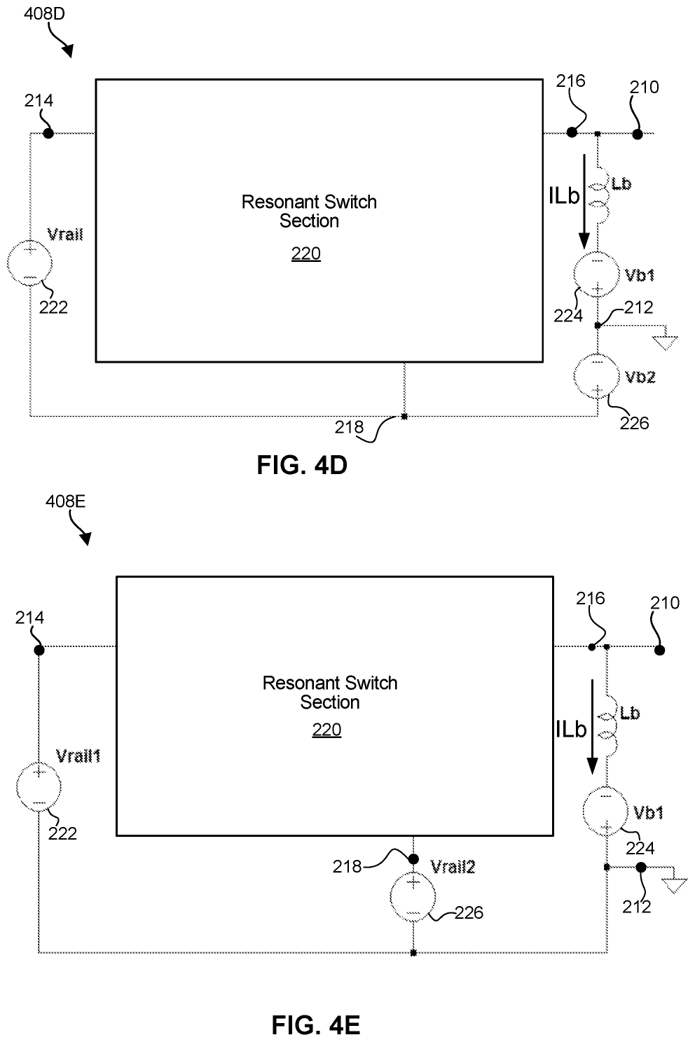

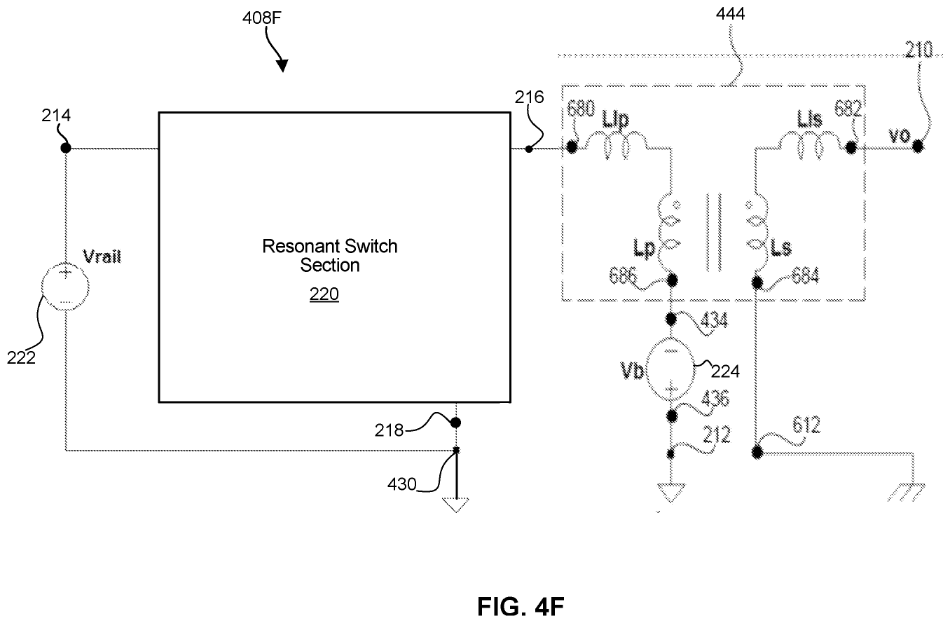

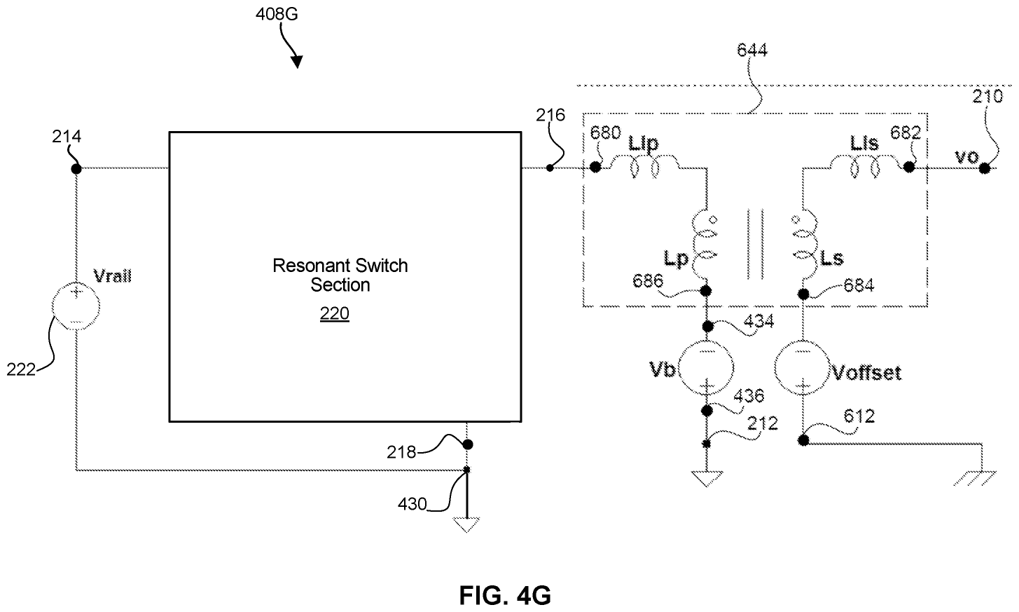

Referring to FIG. 2, shown is an exemplary bias supply 208 that may be utilized to implement the bias supplies 108 described with reference to FIG. 1. The bias supply 208 generally represents many variations of bias supplies described further herein with reference to FIGS. 4A, 4B, 4C, 4D, 4E, 4F, and 4G to apply a periodic voltage function. Thus, reference to the bias supply 208 generally refers to the bias supply 208 depicted in FIG. 2 and the bias supplies 408A to 408G described further herein. As shown, the bias supply 208 includes an output 210 (also referred to as an output node 210), a return node 212, a resonant switch section 220 and a power section 230, and the resonant switch section 220 is coupled to the power section 230 at three nodes: a first node 214, a second node 216, and a third node 218. In general, the bias supply 208 functions to apply a periodic voltage function between the output node 210 and the return node 212. Current delivered to a load through the output node 210 is returned to the bias supply 208 through the return node 212 that may be common with the load.

In many implementations as disclosed further herein, the resonant switch section 220 is configured to enable a first current pathway between the first node 214 and the second node 216 to be periodically connected and disconnected, which results in an application of periodic voltage waveform between the output node 210 and the return node 212. For example, the resonant switch section 220 may comprise a controllable switch and one or more inductive elements arranged to provide the first current pathway between the first node 214 and the second node 216 and a second current pathway between the second node 216 and the third node 218. In addition, the first current pathway and the second current pathway may be configured so that current in the first and second current pathways is unidirectional.

As described further herein, the power section 230 may include a combination of one or more voltage sources and inductive elements. Although not depicted in FIG. 2 for clarity and simplicity, the bias supply 208 may be coupled to a controller and/or include a controller that is coupled to the resonant switch section 220 and or the power section 230. Variations of each of the resonant switch section 220 and the power section 230, and details of the interoperation of the resonant switch section 220 with the power section 230, are disclosed further herein, but first, it is helpful to understand aspects of a plasma load.

Referring briefly to FIG. 3, shown is a schematic drawing that electrically depicts aspects of an exemplary plasma load within the plasma processing chamber 101. As shown, the plasma processing chamber 101 may be represented by a chuck capacitance C_{ch} (that includes a capacitance of a chuck and workpiece 103) that is positioned between an input 310 (also referred to as an input node 310) to the plasma processing chamber 101 and a node representing a sheath voltage, Vs, at a surface of the workpiece 103 (also referred to as substrate 103). In addition, a return node 312 (which may be a connection to ground) is depicted. The plasma 102 in the processing chamber is represented by a parallel combination of a sheath capacitance C_{S}, a diode, and a current source. The diode represents the non-linear, diode-like nature of the plasma sheath that results in rectification of the applied AC field, such that a direct-current (DC) voltage drop, appears between the workpiece 103 and the plasma 102.

Referring to FIGS. 4A, 4B, 4C, 4D, 4E, 4F, and 4G, shown are bias supplies 408A, 408B, 408C, 408D, 408E, 408F, 408G, respectively, that may be utilized to realize the bias supply 208, and hence, bias supplies 408A to 408G may be utilized as the bias supplies 108 depicted in FIG. 1. As shown, each of the bias supplies 408A to 408G comprises a resonant switch section 220 in connection with variations of the power section 230 that comprise one or more voltage sources and inductors arranged in a variety of topologies. More specifically, in each of FIGS. 4A, 4B, 4C, 4D, 4E, 4F, and 4G, the depicted voltage sources, inductors, and interconnections between the voltage sources and inductors make up variations of the power section 230.

As shown, each of the bias supplies is configured to apply a periodic voltage comprising: an output node 210 and a return node 212, and each of the bias supplies comprises a resonant switch section 220 that is coupled to a power section at a first node 214, a second node 216, and a third node 218. The power section of each of the bias supplies 408A, 408B, 408C, 408D, 408E, 408F, 408G varies from other ones of the bias supplies, but each of the bias supplies 408A, 408B, 408C, 408D, 408E, 408F, 408G comprises a first voltage source 222 coupled between the third node 218 and the first node 214 and a second voltage source 224 coupled to the return node 212. As discussed further herein switching action of the resonant switch section 220 results in an application of the periodic voltage between the output node 210 and the return node 212.

In the variation depicted in FIG. 4A, a first inductor. Lb, is positioned between the second node 216 and a negative terminal of the second voltage source 224. In addition, an inductance, Lext, is positioned between the second node 216 and the output node 210. The inductance, Lext, may be a stray inductance or an intentionally added inductor.

In the variations depicted in FIGS. 4B, 4C, 4D, and 4F, the first inductor, Lb, is positioned between the output node 210 and the second voltage source 224. It is also noted that, in the variations depicted in FIGS. 4B, 4C, 4D, and 4F, the second node 216 and the output node 210 are a common node so that the first inductor, Lb, is positioned between the second node 216 and the second voltage source 224. As shown in FIGS. 4B, 4C, 4D, and 4F, the first inductor, Lb, is coupled between the output node 210 and a negative terminal of the second voltage source 224.

In the variations of FIGS. 4B and 4C, the return node 212 is a connection point between the first inductor, Lb, and the second voltage source. 224 In the variations depicted in FIGS. 4A, 4D, and 4E, the positive node of the second voltage source 224 is coupled to the return node 212, and in the variations depicted in FIGS. 4B and 4C, a negative terminal of the second voltage source 224 is coupled to the return node.

The bias supplies 408D, 408E depicted in FIGS. 4D and 4E depict variations that comprise a third voltage source 226 where a negative terminal of the third voltage source 226 is connected to the return node 212. In the variation of FIG. 4D, a positive terminal of the third voltage source 226 is connected to the third node 218 and the negative terminal of the first voltage source 226, and in the variation of FIG. 4E, a positive terminal of the of the third voltage source 226 is connected to the third node 218 and the negative terminal of the third voltage source 226 is coupled to the negative terminal of the first voltage source 222.

In the example bias supply 408D, the third voltage source 226 adds a DC compensation voltage, which may be used to adjust a chucking force applied by an electrostatic chuck within the plasma processing chamber 101. In some modes of operation, the total voltage applied by second voltage source 224 and the third voltage source 226 is set to a constant value so that the voltage applied by the second voltage source 224 is decreased when the voltage applied by the third voltage source 226 is increased.

Referring next to FIG. 4F, shown is another example bias supply 408F that may be used to implement the bias supply 208. As shown, a transformer 444 is used to apply power to the output node 210 of the bias supply. The transformer 444 includes a primary winding (represented by Llp and Lp) and a secondary winding (represented by Lls and Ls). A first node 680 of the primary winding of the transformer 444 is coupled to the second node 216. A first node 682 of the secondary winding of the transformer 444 is coupled to the output node 210. And a second node 684 of the secondary winding of the transformer 444 is coupled to a secondary-side return node 612 on the secondary side of the transformer 444. The first voltage source 222 is coupled between the first node 214 and the third node 218 of the resonant switch section 220. The second voltage source 224 is coupled between a second node 686 of the primary winding of the transformer 444 and the return node 212.

The bias supply 408G shown in FIG. 4G is the same as the bias supply shown in FIG. 4G except that an offset-voltage-source, Voffset, is coupled between the second node 684 of the secondary winding of the transformer 444 and the secondary-side return node 612. More specifically, a positive terminal of the offset-voltage-source, Voffset, is coupled to the secondary-side return node 612 and a negative terminal offset-voltage-source, Voffset, is coupled to the second node 684 of the transformer 444.

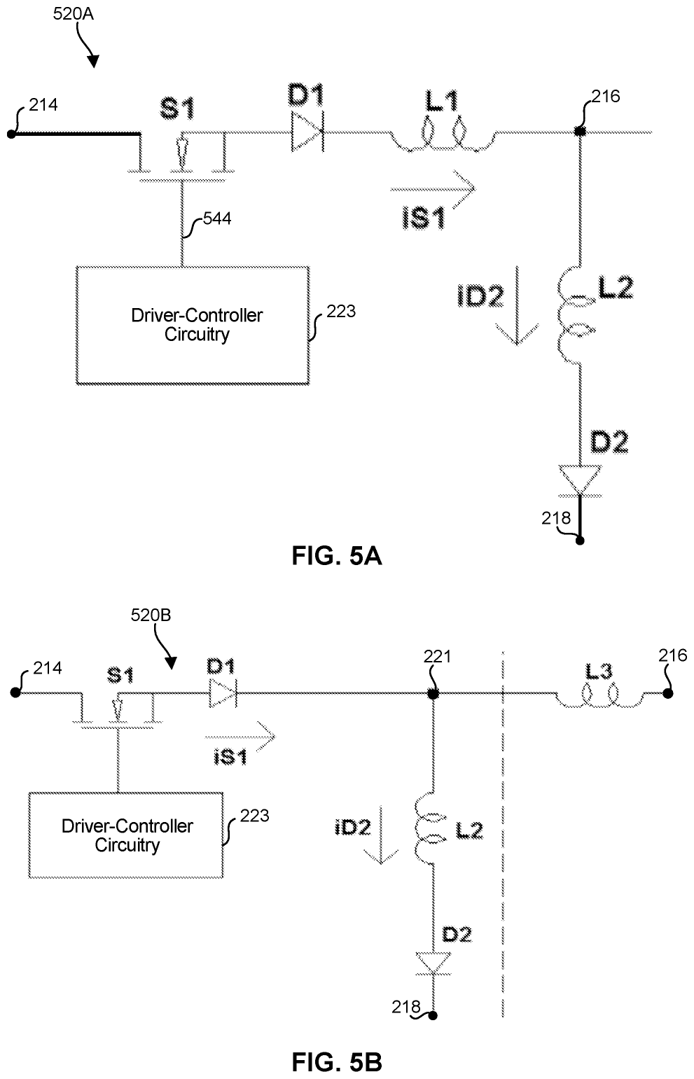

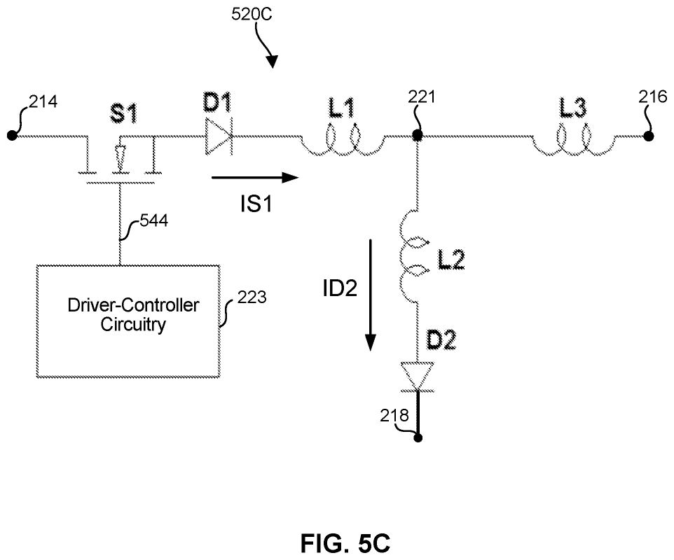

Referring next to FIGS. 5A, 5B, and 5C, shown are variations of the resonant switch section 220. As shown, the resonant switch section 520A, 520B, 520C comprises the first node 214, the second node 216, and the third node 218, and each of the variations comprises a first current pathway (for current iS1), between the first node 214 and the second node 216. The first current pathway comprises a series combination of a switch, S1, and a diode, D1. In addition, each of the variations of the resonant switch section 520A, 520B, 520C comprises second current pathway (for current iD2), (between the first current pathway and the third node 218), which comprises a second diode, D2, and an inductive element, L2. As shown, the resonant switch section 520A, 520B, 520C also comprises driver-controller circuitry 223 that is coupled to the switch, S1, via a drive signal line 544.

It should be recognized that each of the diode, D1, and the diode, D2, may be realized by a plurality of diodes. For example, either diode, D1, and/or diode, D2, may be realized by a plurality of series-connected diodes (to enhance voltage capability). Or either diode, D1, and/or diode, D2, may be realized by a plurality of diodes arranged in parallel (to enhance current capability).

In the resonant switch section 520A the first current pathway comprises a series combination of the switch, S1, an inductive element, L1, and the diode, D1, arranged between the first node 214 and the second node 216. It should be recognized that (because the switch, S1, the diode, D1, and the inductor, L1 are arranged in series), the order in which the switch, S1, the diode D1, and the inductor, L1 are positioned (between the first node 214 and the second node 216) may vary.

In the resonant switch section 520B the first current pathway comprises the switch, S1, arranged in series with the diode, D1, and the series combination of the switch, S1, and the diode, D1, is coupled between the first node 214 and a fourth node 221. In addition, the second current path (for iD2) comprises a series combination of the inductor, L2, and the diode, D2, between the fourth node 221 and the third node 218. In addition, the resonant switch section 520B comprises an inductor, L3, between the fourth node 221 and the second node 216.

Referring to FIG. 5C, the resonant switch section 520C is similar to the resonant switch section 520B except the first current pathway comprises a series combination of the switch, S1, inductive element, L1, and the diode, D1, arranged between the first node 214 and the fourth node 221. It should be recognized that (because the switch, S1, the diode, D1, and the inductor, L1 are arranged in series), the order in which the switch, S1, the diode D1, and the inductor, L1 are positioned (between the first node 214 and the fourth node 216) may vary.

In many implementations, the switch, S1 is realized by a field-effect switch such as metal-oxide semiconductor field-effect transistors (MOSFETS), and in some implementations, the switch, S1, is realized by silicon carbide metal-oxide semiconductor field-effect transistors (SiC MOSFETs) or gallium nitride metal-oxide semiconductor field-effect transistors (GaN MOSFETs). As another example, the switch, S1, may be realized by an insulated gate bipolar transistor (IGBT). In these implementations, the driver-controller circuitry 223 may comprise an electrical driver known in the art that is configured to apply power signals to the switch, S1, via drive signal line 544 responsive to signals from a controller. It is also contemplated that the controller may be capable of applying a sufficient level of power so that a separate electrical driver may be omitted. It is also contemplated that the drive signal line 544 may be an optical line to convey optical switching signals. And the switch, S1, may switch in response to the optical signal and/or optical signals that are converted to an electrical drive signal.

It should be recognized that the switch, S1, generally represents one or more switches that are capable of closing and opening to connect and disconnect, respectively, the first current pathway between the first node 214 and the second node 216. For example, the switch, S1, may be realized by a plurality of switches arranged is series (for enhanced voltage capability). Or the switch, S1, may be realized by a plurality of switches arranged is parallel (for enhanced current capability). In these variations, one of ordinary skill in the art will recognize that each switch may be synchronously driven by a corresponding drive signal.

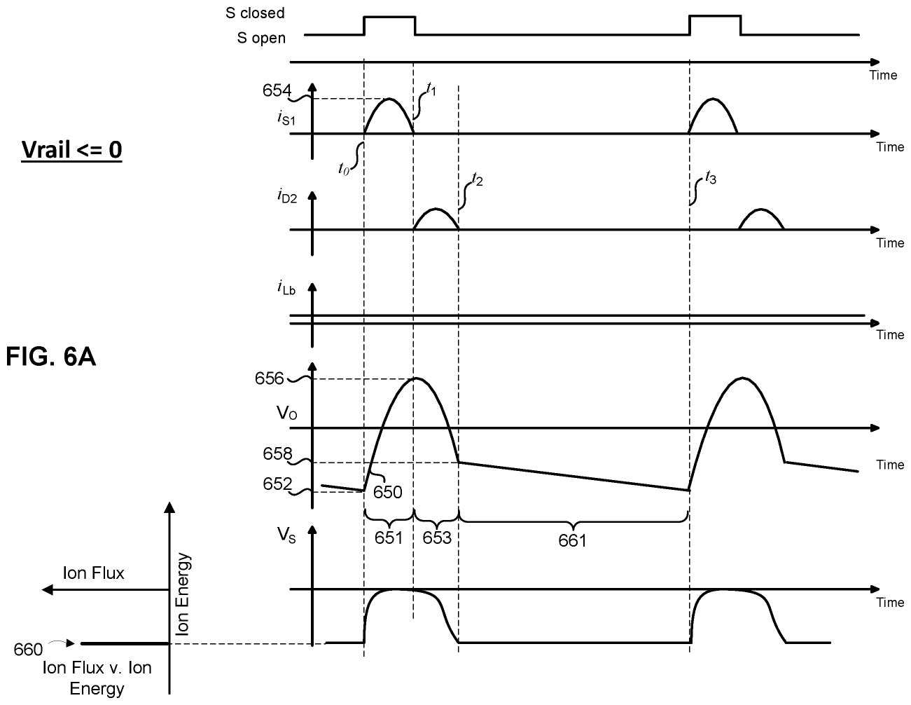

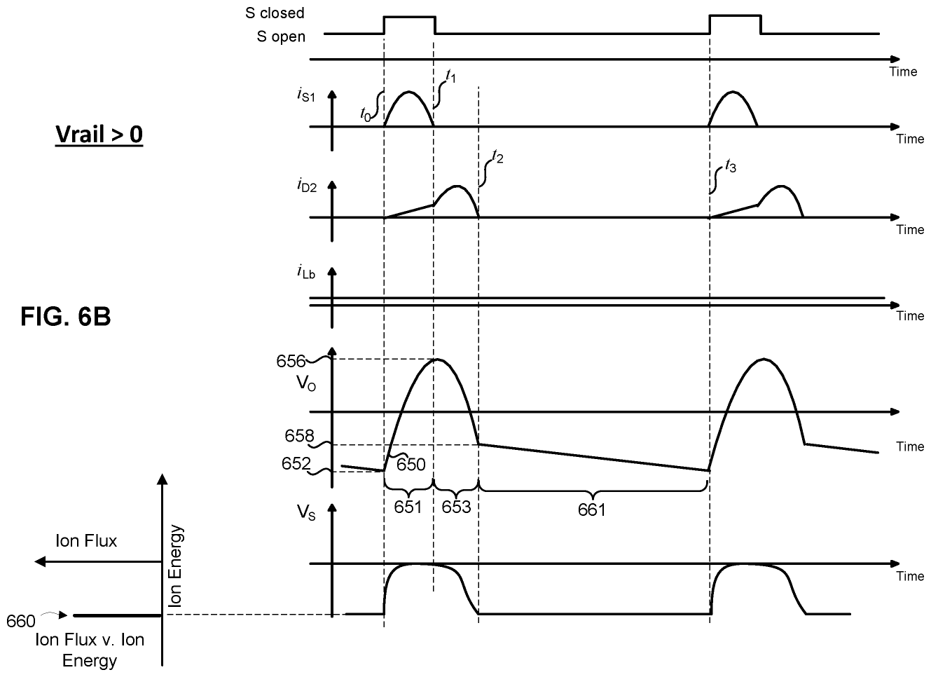

Referring next to FIGS. 6A and 6B, shown are graphs depicting operational aspects of the variations of the bias supply 208 disclosed herein to achieve an asymmetrical periodic voltage between the output node 210 and the return node 212 of the bias supply 208 during a full cycle of an asymmetric periodic voltage, Vo, from the time t0 to the time t3. More specifically, FIG. 6A depicts operational aspects of the bias supply 208 when a voltage (Vrail) of the first voltage source 222 is less than or equal to zero. And FIG. 6B depicts operational aspects of the bias supply 208 when the voltage (Vrail) of the first voltage source 222 is greater than zero. Also depicted in FIGS. 6A and 6B is a sheath voltage, Vs, that corresponds to the asymmetrical periodic voltage. As shown, the asymmetric periodic voltage achieves a sheath voltage, Vs, that is generally negative to attract ions to impact a surface of the workpiece to enable etching of the workpiece 103.

As shown in FIG. 6A, when the switch, S1, is closed at a time t0, the current pathway (comprising the switch, S1, and diode, D1) connects the first node 214 to the second node 216 and unidirectional current, iS1, begins to increase from zero current at the time, t0, and the asymmetrical periodic voltage, V0, (relative to the return node 212) applied at the output node 210 begins to move (over a first portion 651 of the of the periodic voltage waveform) from a first negative voltage 652 to a positive peak voltage 656. As shown, the current, iS1, increases to a peak value 654 and then decreases to zero at a time, t1, when the switch, S1, is opened.

As depicted, when the switch, S1, is opened, the current, iS1, through the first current pathway drops to zero and the asymmetric periodic voltage drops from the positive peak voltage 656. As shown, when the switch, S1, is opened, (during a second portion 653 of the asymmetrical waveform) unidirectional current, iD2, begins to flow through the second current pathway through the second diode, D2, peaks, and then drops to zero current flow, from time t1 to a time t2. As shown, the rise and fall of the unidirectional current, iD2, occurs while the asymmetrical periodic voltage changes (during the second portion 653) from the positive peak voltage 656 to a third. negative, voltage level 658. As depicted, during the time from t0 to t2, the first portion 651 of the asymmetric periodic voltage causes the sheath voltage to approach a positive voltage to repel positive charges (that accumulate on the surface of the workpiece while the surface of the workpiece is held at a negative voltage), and the second portion 653 of the asymmetric periodic voltage causes the sheath voltage to become a desired negative voltage (or range of voltages) to achieve an ion flux that achieves a desired ion energy 670.

As depicted, after the unidirectional current, iD2, rises and falls back to a level of zero current, the asymmetrical periodic voltage, V0, becomes more negative (as a negative voltage ramp) during a fourth portion 661 until the switch, S1, is closed again at a time t3. As depicted, a compensation iLb, produced by the second voltage source 224, may be provided during a cycle of the asymmetric periodic voltage to compensate for ion current in the plasma chamber 101. For example, without the compensation current, iLb, that sheath voltage, Vs, may gradually change to become more positive during the fourth portion of the asymmetric periodic voltage, which creates a broader distribution of ion energies, which may be undesirable. But in some variations, the compensation current, iLb, may intentionally be set to overcompensate or undercompensate for ion current in the plasma chamber 101 to create a broader distribution of ion energies. In the modes of operation depicted in FIGS. 6A and 6B, the compensation current, iLb, provides a sheath voltage, Vs, that is substantially constant during the fourth portion 661 of the asymmetrical periodic voltage, Vo.

As shown in FIG. 6B, when the voltage, Vrail, from the first voltage source 222 is greater than zero, the operational aspects of the bias supply 208 are similar to the operational aspects of the bias supply 208 when the voltage, Vrail, from the first voltage source 222 is less than zero except the current, iD2, increases in a ramp-like manner while the switch, S1, is closed so that the current iD2 is non-zero when the switch, S1 is opened at the time, t1.

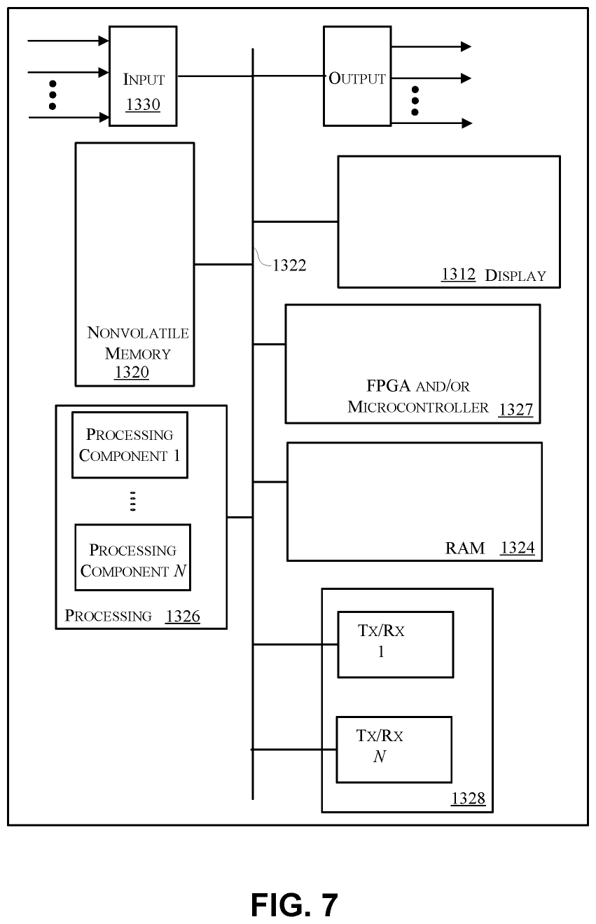

The methods described in connection with the embodiments disclosed herein may be embodied directly in hardware, in processor-executable code encoded in a non-transitory tangible processor readable storage medium, or in a combination of the two. Referring to FIG. 7 for example, shown is a block diagram depicting physical components that may be utilized to realize control aspects disclosed herein. As shown, in this embodiment a display 1312 and nonvolatile memory 1320 are coupled to a bus 1322 that is also coupled to random access memory (“RAM”) 1324, a processing portion (which includes N processing components) 1326, a field programmable gate array (FPGA) 1327, and a transceiver component 1328 that includes N transceivers. Although the components depicted in FIG. 7 represent physical components, FIG. 7 is not intended to be a detailed hardware diagram; thus, many of the components depicted in FIG. 7 may be realized by common constructs or distributed among additional physical components. Moreover, it is contemplated that other existing and yet-to-be developed physical components and architectures may be utilized to implement the functional components described with reference to FIG. 7.

This display 1312 generally operates to provide a user interface for a user, and in several implementations, the display is realized by a touchscreen display. In general, the nonvolatile memory 1320 is non-transitory memory that functions to store (e.g., persistently store) data and processor-executable code (including executable code that is associated with effectuating the methods described herein). In some embodiments for example, the nonvolatile memory 1320 includes bootloader code, operating system code, file system code, and non-transitory processor-executable code to facilitate the execution of a method of biasing a substrate with the single controlled switch.

In many implementations, the nonvolatile memory 1320 is realized by flash memory (e.g., NAND or ONENAND memory), but it is contemplated that other memory types may be utilized as well. Although it may be possible to execute the code from the nonvolatile memory 1320, the executable code in the nonvolatile memory is typically loaded into RAM 1324 and executed by one or more of the N processing components in the processing portion 1326.

The N processing components in connection with RAM 1324 generally operate to execute the instructions stored in nonvolatile memory 1320 to enable execution of the algorithms and functions disclosed herein. It should be recognized that several algorithms are disclosed herein, but some of these algorithms are not represented in flowcharts. Processor-executable code to effectuate methods described herein may be persistently stored in nonvolatile memory 1320 and executed by the N processing components in connection with RAM 1324. As one of ordinarily skill in the art will appreciate, the processing portion 1326 may include a video processor, digital signal processor (DSP), micro-controller, graphics processing unit (GPU), or other hardware processing components or combinations of hardware and software processing components (e.g., an FPGA or an FPGA including digital logic processing portions).

In addition, or in the alternative, non-transitory FPGA-configuration-instructions may be persistently stored in nonvolatile memory 1320 and accessed (e.g., during boot up) to configure a field programmable gate array (FPGA) to implement the algorithms disclosed herein.

The input component 1330 may receive signals (e.g., signals indicative of current and voltage obtained at the output of the disclosed bias supplies). In addition, the input component 1330 may receive phase information and/or a synchronization signal between bias supplies 108 and source generator 112 that are indicative of one or more aspects of an environment within a plasma processing chamber 101 and/or synchronized control between a source generator and the single switch bias supply. The signals received at the input component may include, for example, synchronization signals, power control signals to the various generators and power supply units, or control signals from a user interface. Those of ordinary skill in the art will readily appreciate that any of a variety of types of sensors such as, without limitation, directional couplers and voltage-current (VI) sensors, may be used to sample power parameters, such as voltage and current, and that the signals indicative of the power parameters may be generated in the analog domain and converted to the digital domain.

The output component generally operates to provide one or more analog or digital signals to effectuate the opening and closing of the switch, Si. The output component may also control of the voltage sources described herein.

The depicted transceiver component 1328 includes N transceiver chains, which may be used for communicating with external devices via wireless or wireline networks. Each of the N transceiver chains may represent a transceiver associated with a particular communication scheme (e.g., WiFi, Ethernet, Profibus, etc.).

As will be appreciated by one skilled in the art, aspects of the present disclosure may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present disclosure may take the form of a computer program product embodied in one or more computer readable medium(s) having computer readable program code embodied thereon.

As used herein, the recitation of “at least one of A, B or C” is intended to mean “either A, B, C or any combination of A, B and C.” The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

What is claimed is:

1. A bias supply to apply a periodic voltage comprising:
an output node;
a return node;
a switch coupled to a first node, a second node, and a third node;
a first current pathway between the first node and the second node, the first current pathway comprising a series combination of a switch and a diode;
a second current pathway between the second node and the third node comprising a diode and an inductive element; and
a power section comprising:
a first voltage source coupled between the third node and the first node; and
a second voltage source coupled to the return node;
wherein closing the switch causes unidirectional current in the first and second current pathways to cause an application of the periodic voltage between the output node and the return node.
